(19) United States
(12) Patent Application Publication
(10) Pub. No.: US 2025/0270734 A1
(43) Pub. Date: Aug. 28, 2025

(54) LINERS HAVING FLOW OPENINGS, AND RELATED CHAMBER KITS, PROCESSING CHAMBERS, AND METHODS FOR SEMICONDUCTOR MANUFACTURING

(71) Applicant: Applied Materials, Inc., Santa Clara, CA (US)

(72) Inventors: Toshiyuki NAKAGAWA, Narita-Shi (JP); Shu-Kwan LAU, Sunnyvale, CA (US)

(21) Appl. No.: 18/589,251

(22) Filed: Feb. 27, 2024

(51) Int. Cl. C30B 25/08; C30B 25/14

(52) U.S. Cl. CPC C30B 25/08; C30B 25/14

(57) ABSTRACT

The present disclosure relates to liners having flow openings, and related chamber kits, processing chambers, and methods for semiconductor manufacturing. In one or more embodiments, a liner applicable for semi-conductor manufacturing includes an inner face and an outer face opposing the inner face. The liner includes an inlet opening extending into the inner face and an outlet opening extends into the inner face. The liner includes a curved flow opening extending into the outer face and extending at least partially about the liner. The curved flow opening extends along an azimuthal angle greater than 90 degrees.

### BACKGROUND

### Field

The present disclosure relates to liners having flow openings, and related chamber kits, processing chambers, and methods for semiconductor manufacturing.

### Description of the Related Art

Semiconductor substrates are processed for a wide variety of applications, including the fabrication of integrated devices and microdevices. One method of processing substrates includes depositing a material, such as a semiconductor material or a conductive material, on an upper surface of the substrate. For example, epitaxy is one deposition process that deposit films of various materials on a surface of a substrate in a processing chamber. During processing, various parameters can affect the uniformity of material deposited on the substrate.

However, operations (such as epitaxial deposition operations) can involve corrosion, deposition, and/or contamination on chamber components. For example, gases can leak in between surfaces of chamber components, and the gases can condense on surfaces of chamber components. Such leakage can reduce component lifespans, increase gas consumption, and/or contaminate processed substrates.

Therefore, a need exists for improved apparatuses and methods in semiconductor processing.

### SUMMARY

The present disclosure relates to liners having flow openings, and related chamber kits, processing chambers, and methods for semiconductor manufacturing.

In one or more embodiments, a liner applicable for semi-conductor manufacturing includes an inner face and an outer face opposing the inner face. An inlet opening extends into the inner face and an outlet opening extends into the inner face. A curved flow opening extends into the outer face and extends at least partially about the liner. The curved flow opening extends along an azimuthal angle greater than 90 degrees.

In one or more embodiments, a chamber kit applicable for semi-conductor manufacturing includes a first liner with. The first liner includes a first inner face and a first outer face opposing the first inner face. The first liner includes a first flow opening extending into the first outer face and extending at least partially about the first liner. The first flow opening extends along a first azimuthal angle greater than 90 degrees. The chamber kit also includes a second liner. The second liner includes a second inner face and a second outer face opposing the first inner face. The second liner includes a second flow opening sized and shaped to at least partially align with the first flow opening. The second flow opening extends into the second outer face and extends at least partially about the second liner. The second flow opening extends along a second azimuthal angle greater than 90 degrees.

In one or more embodiments, a processing chamber applicable for semi-conductor manufacturing includes one or more sidewalls at least partially defining a processing volume, a substrate support disposed in the processing volume, and one or more heat sources operable to heat the processing volume. The processing chamber also includes a first liner disposed in the processing volume. The first liner includes a first inner face, a first outer face opposing the first inner face, and a first flow opening that extends into the first outer face and extends at least partially about the first liner. The first flow opening extends along a first azimuthal angle greater than 90 degrees. The processing chamber also includes a second liner at least partially supporting the first liner. The second liner includes a second inner face, a second outer face opposing the first inner face, and a second flow opening at least partially aligning with the first flow opening. The second flow opening extends into the second outer face and extends at least partially about the second liner. The second flow opening extends along a second azimuthal angle greater than 90 degrees.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic side cross-sectional view of a processing chamber, according to one or more embodiments.

FIG. 2 is a schematic partial top cross-sectional view of the processing chamber shown in FIG. 1, according to one or more embodiments.

FIG. 3 is schematic partial front view of the upper flow module and the lower flow module, shown in FIG. 1 according to one or more embodiments.

FIG. 4 is a schematic isometric view of a chamber kit applicable for semi-conductor manufacturing.

FIG. 5 is a schematic isometric view of a chamber kit applicable for semi-conductor manufacturing.

FIG. 6A shows a schematic perspective profile view of material buildup on the chamber body using configurations described herein, according to one or more embodiments.

FIG. 6B is a schematic perspective profile view of material buildup on the chamber body using other configurations.

FIG. 7A is a schematic top isometric view of the upper liner shown in FIGS. 1 and 4, according to one or more embodiments.

FIG. 7B is a schematic bottom isometric view of the upper chamber liner shown in FIG. 7A, according to one or more embodiments.

FIG. 7C is a schematic bottom view of the upper chamber liner shown in FIG. 7A, according to one or more embodiments.

FIG. 8A is a schematic isometric view of the middle chamber liner shown in FIGS. 1 and 4, according to one or more embodiments.

FIG. 8B is a schematic top view of the middle liner shown in FIG. 8A, according to one or more embodiments.

FIG. 8C is a schematic bottom view of the middle liner shown in FIG. 8A, according to one or more embodiments.

FIG. 9A is a schematic isometric view of the lower liner shown in FIGS. 1 and 4, according to one or more embodiments.

FIG. 9B is a schematic top view of the lower liner shown in FIG. 9A, according to one or more embodiments.

FIG. 10 is a schematic block diagram view of a method of substrate processing for semiconductor manufacturing, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to liners having flow openings, and related chamber kits, processing chambers, and methods for semiconductor manufacturing.

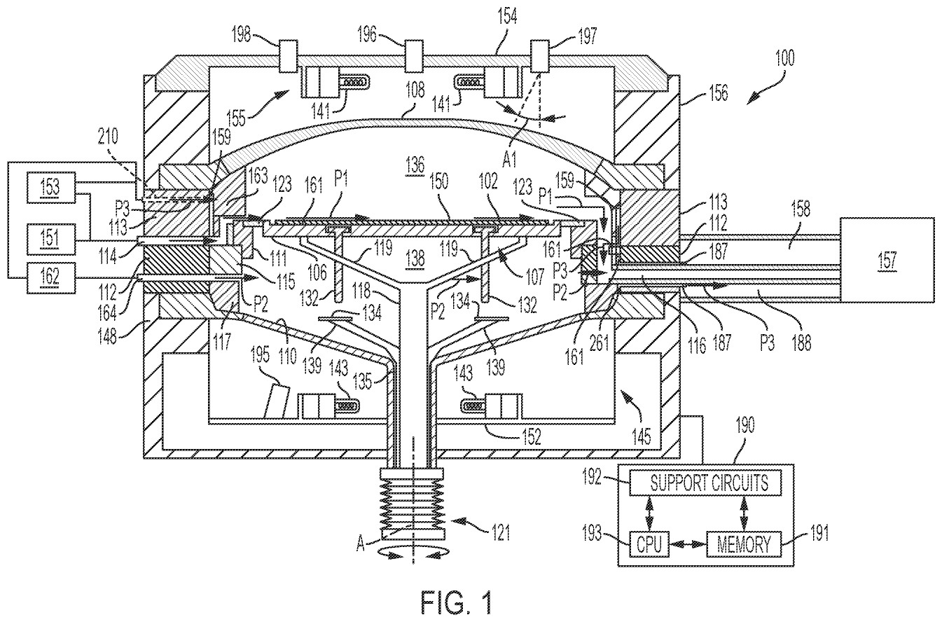

FIG. 1 is a schematic side cross-sectional view of a processing chamber 100, according to one or more embodiments. The processing chamber 100 is a deposition chamber. In one or more embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102. The processing chamber 100 is shown in a processing condition in FIG. 1.

The processing chamber 100 includes an upper body 156, a lower body 148 disposed below the upper body 156, an upper flow module 113, and a lower flow module 112 disposed between the upper body 156 and the lower body 148. The upper body 156, the upper flow module 113, the lower flow module 112, and the lower body 148 form a chamber body. Disposed within the chamber body is a substrate support 106, an upper window 108 (such as an upper dome), a lower window 110 (such as a lower dome), and one or more heat sources 141, 143. The one or more heat sources 141, 143 include a plurality of upper heat sources 141 and a plurality of lower heat sources 143. In one or more embodiments, the upper heat sources 141 include upper lamps and the lower heat sources 143 include lower lamps. In one or more embodiments, the lamps include halogen lamps. In one or more embodiments, the lamps are operable to emit infrared light and/or ultraviolet light. The present disclosure contemplates that other heat sources may be used (in addition to or in place of the lamps) for the various heat sources described herein. For example, resistive heaters, light emitting diodes (LEDs), and/or lasers may be used for the various heat sources described herein.

The substrate support 106 is disposed between the upper window 108 and the lower window 110. The substrate support 106 supports the substrate 102. In one or more embodiments, the substrate support 106 includes a susceptor. Other substrate supports (including, for example, a substrate carrier and/or one or more ring segment(s) that support one or more outer regions of the substrate 102) are contemplated by the present disclosure. The plurality of upper heat sources 141 are disposed between the upper window and a lid 154. The plurality of upper heat sources 141 form a portion of the upper heat source module 155.

The plurality of lower heat sources 143 are disposed between the lower window 110 and a floor 152. The plurality of lower heat sources 143 form a portion of a lower heat source module 145. The upper window 108 is an upper dome and/or is formed of an energy transmissive material, such as quartz. The lower window 110 is a lower dome and/or is formed of an energy transmissive material, such as quartz.

A processing volume 136 and a purge volume 138 are formed between the upper window 108 and the lower window 110. The processing volume 136 and the purge volume 138 are part of an internal volume defined at least partially by the upper window 108, the lower window 110, and one or more liners 163, 115, 117. In one or more embodiments, the chamber includes three liners 163, 115, 117. In one or more embodiments, an upper liner 163, a middle liner 115, and a lower liner 117. The one or more liners 163, 115, 117 are disposed inwardly of the chamber body.

The internal volume has the substrate support 106 disposed therein. The substrate support 106 includes a top surface on which the substrate 102 is disposed. The substrate support 106 is attached to a shaft 118. In one or more embodiments, the substrate support 106 is connected to the shaft 118 through one or more arms 119 connected to the shaft 118. The shaft 118 is connected to a motion assembly 121. The motion assembly 121 includes one or more actuators and/or adjustment devices that provide movement and/or adjustment for the shaft 118 and/or the substrate support 106 within the processing volume 136.

The substrate support 106 may include lift pin holes 107 disposed therein. The lift pin holes 107 are each sized to accommodate a lift pin 132 for lifting of the substrate 102 from the substrate support 106 before or after a deposition process is performed. The lift pins 132 may rest on lift pin stops 134 when the substrate support 106 is lowered from a process position to a transfer position. The lift pin stops 134 can include a plurality of arms 139 that attach to a shaft 135.

The upper flow module 113 and the lower flow module 112 include one or more gas inlets 114 (e.g., a plurality of gas inlets), one or more purge gas inlets 164 (e.g., a plurality of purge gas inlets), and one or more gas exhaust outlets 116. The one or more gas inlets 114 and the one or more purge gas inlets 164 are disposed on the opposite side of the flow module 112 from the one or more gas exhaust outlets 116. The one or more gas exhaust outlets 116 are formed in one or more flow housings 158 (e.g., gas boxes). In one or more embodiments the upper flow module 113 and/or the lower flow module 112 include one or more metallic bodies. The one or more metallic bodies can include, for example, stainless steel and/or aluminum. Other materials are contemplated. In one or more embodiments the upper flow module 113 and lower flow module 112 abut respectively against outer faces of the liners 163, 115, 117. A pre-heat ring 123 is disposed below the one or more gas inlets 114 and the one or more gas exhaust outlets 116. The pre-heat ring 123 includes a complete ring or one or more ring segments. The pre-heat ring 123 is disposed on top of a support liner 111, above the one or more purge gas inlets 164. The one or more liners 163, 115, 117 are disposed on an inner surface of the flow module 112 and protects the flow module 112 from reactive gases used during deposition operations and/or cleaning operations. The gas inlet(s) 114 and the purge gas inlet(s) 164 are each positioned to flow a respective one or more process gases P1 and one or more purge gases P2 parallel to the top surface 150 of a substrate 102 disposed within the processing volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to the one or more exhaust pump(s) 157. The exhaust pump 157 can assist in the controlled deposition of a layer on the substrate 102. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). The one or more purge gases P2 supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen (H) and/or chlorine (CI). In one or more embodiments, the one or more process gases P1 include silicon phosphide (SiP) and/or phosphine (PH₃), and the one or more cleaning gases include hydrochloric acid (HCl).

In one or more embodiments, one or more gases P3 flow through an upper liner purge inlet 210 into a first curved flow opening 159 of the upper liner 163 and a second curved flow opening 259 of the middle liner 115. The one or more gases P3 flow in addition to the flow of the one or more purge gases P2. In one or more embodiments, the one or more gases P3 include one or more purge gases. The one or more gases P3 can have the same or different composition as the one or more purge gases P2. The first curved flow opening 159 and the second curved flow opening 259 are located between the upper flow module 113 and the upper liner 163 and the middle liner 115. The first and second curved flow openings 159, 250 together define a flow channel between the upper and lower flow modules 112, 113 on one side, and the upper liner 163 and the middle liner 115 on another side. The one or more gases P3 then flow along a curved path in the flow channel around the outside of the upper liner 163 and the middle liner 115 towards the gas exhaust outlet 116. The one or more gases P3 flows from the flow channel through one or more through holes 161 located in the middle liner 115. The one or more gases P3 then flow through the through holes 161 into the gas exhaust outlet 116 where the one or more gases P3 can be exhausted through the one or more flow housings 158.

The upper flow module 113 and the lower flow module 112 (which can be at least part of a sidewall of the processing chamber 100) include the one or more gas inlets 114 in fluid communication with the processing volume 136. The one or more gas inlets 114 are in fluid communication with one or more flow gaps between the upper liner 163 and the middle liner 115.

During a deposition operation (e.g., an epitaxial growth operation), the one or more process gases P1 flow through the one or more gas inlets 114, through the one or more gaps, and into the processing volume 136 to flow over the substrate 102.

The present disclosure contemplates that the one or more purge gases P2 can be supplied to the purge volume 138 (through the one or more purge gas inlets 164) during the deposition operation, and exhausted from the purge volume 138. The one or more purge gases P2 flow simultaneously with the flowing of the one or more process gases P1 and/or the one or more gases P3. The one or more process gases P1 are exhausted through gaps between the upper liner 163 and the middle liner 115. The one or more process gases P1, the one or more purge gases P2, and the one or more gases P3 are exhausted through the one or more gas exhaust outlets 116.

In one or more embodiments the one or more gases P3 flow in a second flow channel 261. The one or more gases P3 flow from the second flow channel 261 and around the outside of the one or more flow housings 158 through in one or more gaps 187 between the one or more flow housings 158 and the lower flow module 112. The one or more gases P3 flow from the one or more gaps 187 and into an outer exhaust volume 188 that is fluidly connected to the exhaust pump 157. The present disclosure contemplates that that the one or more gases P3 can be separately exhausted through one or more second gas exhaust outlets that are separate from the one or more gas exhaust outlets 116.

During a cleaning operation, one or more cleaning gases flow through the one or more gas inlets 114, through the one or more gaps (between the upper liner 163 and the middle liner 115), and into the processing volume 136.

The processing system includes one or more sensor devices 195, 196, 197, 198 (e.g., temperature sensors) configured to measure parameter(s) (e.g., temperature(s)) within the processing chamber 100. In one or more embodiments, the one or more temperature sensor devices 195, 196, 197, 198 include a central sensor device 196 and one or more outer sensor devices 195, 197, 198. A controller 190 (described below) can control the one or more sensor devices 195, 196, 197, 198, and can conduct method(s) analyzing uniformity of substrate processing using at least one of the one or more sensor devices 195, 196, 197, 198. In one or more embodiments, the one or more sensor devices 195, 196, 197, 198 each include a sensor that includes one or more of silicon (Si), carbon (C), gallium (Ga), and/or nitrogen (N). In one or more embodiments, the one or more sensor devices 195, 196, 197, 198 each include a silicon sensor, a silicon carbide (SiC) sensor, and/or a gallium nitride (GaN) sensor. In one or more embodiments, each sensor device 195, 196, 197, 198 is a pyrometer and/or optical sensor, such as an optical pyrometer. The present disclosure contemplates that sensor devices other than pyrometers may be used, and/or one or more of the sensor devices 195, 196, 197, 198 can measure properties (such as metrology properties) other than temperature.

In one or more embodiments, the one or more sensor devices 195, 196, 197, 198 include one or more upper sensor devices 196, 197, 198 disposed above the substrate 102 and adjacent the lid 154, and one or more lower sensor devices 195 disposed below the substrate 102 and adjacent the floor 152. The present disclosure contemplates that at least one of the one or more lower sensor devices 195 can be vertically aligned below at least one of the upper sensor devices 196, 196, 197 (such as outer sensor device 197).

Each sensor device 195, 196, 197, 198, can be a single-wavelength sensor device or a multi-wavelength (such as dual-wavelength) sensor device. In one or more embodiments, the system including the process chamber 100 includes any one, any two, or any three of the four illustrated sensor devices 195, 196, 197, 198. In one or more embodiments, the process chamber 100 includes one or more additional sensor devices, in addition to the sensor devices 195, 196, 197, 198. In one or more embodiments, the process chamber 100 may include sensor devices disposed at different locations and/or with different orientations than the illustrated sensor devices 195, 196, 197, 198.

As shown, a controller 190 is in communication with the processing chamber 100 and is used to control processes and methods, such as the operations of the methods described herein. The controller 190 is configured to receive data or input as sensor readings from sensor(s) (such as one or more of the sensor devices 195, 196, 197, 198). The sensor devices can include, for example: sensor devices that monitor growth of layer(s) on the substrate 102; and/or sensor devices that monitor temperatures of the substrate 102, the substrate support 106, and/or the liners 163, 115, 117. As described the one or more sensor devices can include, for example pyrometers.

The controller 190 includes a central processing unit (CPU) 193 (e.g., a processor), a memory 191 containing instructions, and support circuits 192 for the CPU 193. The controller 190 controls various items directly, or via other computers and/or controllers. In one or more embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like. Operational parameters (e.g., a power applied to the heat sources 141, 143, a cleaning recipe, and/or a processing recipe) and operations are stored in the memory 191 as a software routine that is executed or invoked to turn the controller 190 into a specific purpose controller to control the operations of the various chambers/modules described herein. The controller 190 is configured to conduct any of the operations described herein. The instructions stored on the memory, when executed, cause one or more of the operations described herein to be conducted in relation to the processing chamber 100. The controller 190 and the processing chamber 100 are at least part of a system for processing substrates.

The various operations described herein can be conducted automatically using the controller 190, or can be conducted automatically or manually with certain operations conducted by a user.

The controller 190 is configured to control the deposition, the cleaning, the rotational position, the heating, and gas flow through the processing chamber 100 by providing an output to the controls for the sensor devices 195, 196, 197, 198, the upper heat sources 141, the lower heat sources 143, the process gas source 151, the purge gas source 162, the motion assembly 121, and/or the exhaust pump 157.

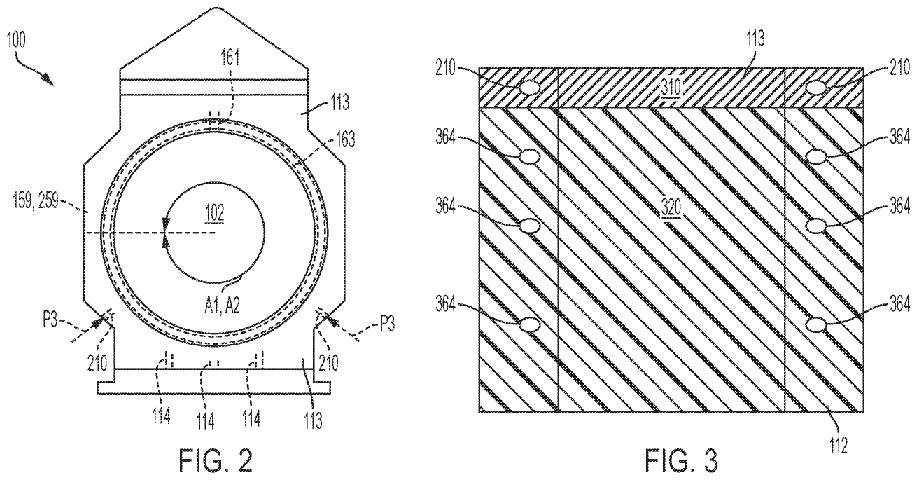

FIG. 2 is a schematic partial top cross-sectional view of the processing chamber 100 shown in FIG. 1, according to one or more embodiments. For visual clarity purposes, the upper flow module 113 is shown schematically and without hatching in FIG. 2.

In one or more embodiments, the purge gas P2 flows through the upper liner purge inlet 210 and into the first and second curved flow openings 159, 259. The first and second curved flow openings 159, 259 are located on the outer faces of the upper liner 163 and the middle liner 115 (FIG. 1). The first curved flow opening 159 and the second curved flow opening 259 extend respectively around the upper liner 163 and the middle liner 115 along a respective azimuthal angle A1, A2 greater than 90 degrees. The first and second curved flow openings 159, 259 define a volume between the upper flow module 113 and the outer faces of the upper liner 163 and the middle liner 115. The one or more gases P3 flow along the first and second curved flow openings 159, 259 from the upper liner purge inlets 210 towards the one or more through holes 161.

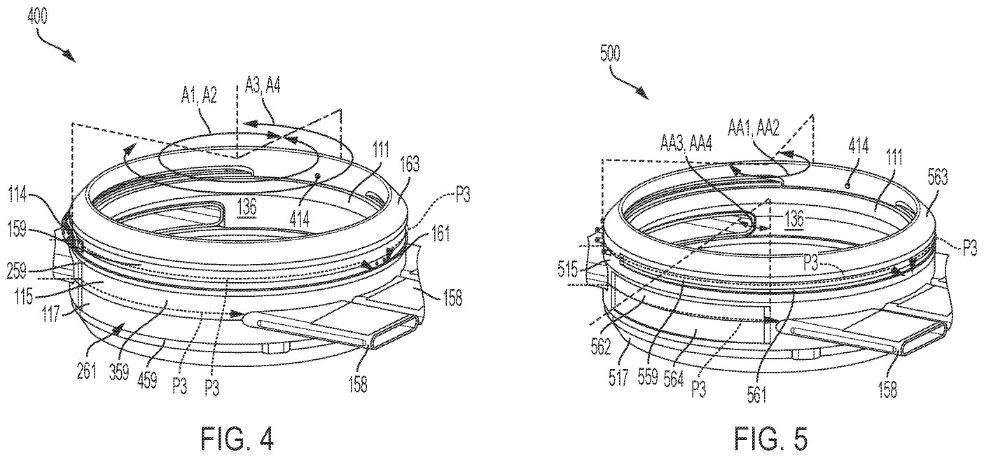

FIG. 3 is schematic partial front view of the upper flow module 113, and the lower flow module 112 shown in FIG. 1, according to one or more embodiments.

In one or more embodiments, the upper flow module 113 includes a front face 310. The lower flow module 112 includes a front face 320. The upper flow module 113 includes a plurality of upper liner purge inlets 210 disposed in the upper flow module 113 on opposite sides of one another with respect to the front face 310. The upper liner purge inlets 210 connect to the first curved flow opening 159 (FIG. 2) that extends between the plurality of upper liner purge inlets 210 along the outer face of the upper liner 163 (FIG. 2) along the first azimuthal angle A1 of at least 90 degrees. The lower flow module 112 includes a plurality of lower purge gas inlets 364 disposed in the lower flow module 112 on opposite sides of one another with respect to the front face 320. The lower purge gas inlets 364 supply the one or more gases P3 to the second flow channel 261.

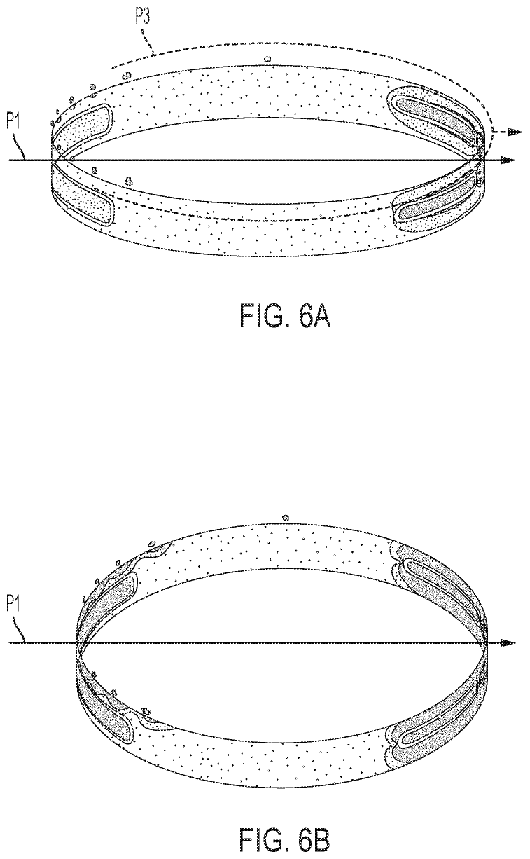

FIG. 4 is a schematic isometric view of a chamber kit 400 applicable for semiconductor manufacturing, according to one or more embodiments. The chamber kit 400 includes one or more aspects, features components, operations, and/or properties of the processing chamber 100 shown in FIGS. 1-4.

The chamber kit 400 includes the upper liner 163, the middle liner 115, and the lower liner 117 as shown in FIG. 1. The liners 163, 115, 117 are formed from an opaque material such as silicon carbide (SiC), opaque quartz (e.g., black quartz, white quartz, and/or grey quartz), and/or graphite coated with silicon carbide and/or opaque quartz. The upper liner 163 includes a side flow inlet 414 through which one or more process gases can flow into the process volume 136 along a direction oriented at an angle relative to the one or more process gases P1 shown in FIG. 1. The one or more gases P3 flow through the upper liner purge inlets 210 (FIG. 3) into the first curved flow opening 159 and the second curved flow opening 259. The first curved flow opening 159 extends along the first azimuthal angle A1 greater than 90 degrees around the outer face of the upper liner 163. The second curved flow opening 259 extends along the second azimuthal angle A2 greater than 90 degrees along the outer face of the middle liner 115. The one or more gases P3 then flow through the one or more through holes 161 (a pair of through holes 161 are shown) extending into the middle liner 115. The one or more through holes 161 extending between the second curved flow opening 259 and the one or more gas exhaust outlets 116.

In one or more embodiments, the one or more gases P3 flow through the purge gas inlets (FIG. 3), into the second flow channel 261. The second flow channel 261 is defined by a third curved flow opening 359 formed in the middle liner 115 and a fourth curved flow opening 459 formed in the lower liner 117. The third curved flow opening 359 is between the middle liner 115 and the lower flow module 112, and the fourth curved flow opening 459 is between the lower liner 117 and the lower flow module 112 to define the second flow channel 261. The third curved flow opening 359 extends along a third azimuthal angle A3 greater than 90 degrees around the outer face of the middle liner 115. The fourth curved flow opening 459 extends along a fourth azimuthal angle A4 greater than 90 degrees along the outer face of the lower liner 117. The third curved flow opening 359 is a recess in the outer face of the middle liner 115 and the fourth curved flow opening 459 is a recess in the outer face of the lower liner 117. The one or more gases P3 flow along the third and fourth curved flow openings 359, 459 around the flow housings 158 through the one or more gaps 187.

In one or more embodiments, one or more (such as one or all) of the azimuthal angles A1-A4 of the first, second, third, and curved flow openings are the same. In one or more embodiments, the first azimuthal angle A1 is equal to the second azimuthal angle A1. In one or more embodiments the one or more (such as one or all) of the azimuthal angles A1-A4 of the first, second, third, and fourth flow openings are different from each other. In one or more embodiments, the third angle A3 and/or the fourth angle A4 are less than the first angle A1 and/or the second angle A2. In one or more embodiments one or more (such as one or all) of the azimuthal angles A1-A4 of the first, second, third, and fourth flow openings are greater than 180 degrees, such as greater than 270 degrees, for example about 360 degrees. In one or more embodiments, the first azimuthal angle A1 and/or the second azimuthal angle A2 is greater than 270 degrees, for example about 360 degrees.

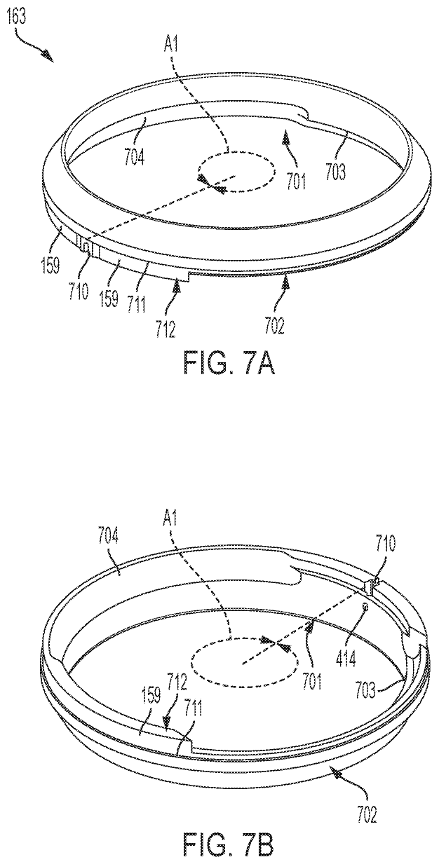

FIG. 5 is a schematic isometric view of a chamber kit 500 applicable for semiconductor manufacturing, according to one or more embodiments. The chamber kit 500 includes one or more aspects, features components, operations, and/or properties of the chamber kit 400 in FIG. 4.

In one or more embodiments, the one or more gases P3 flow through the upper liner purge inlets 210 (FIG. 3) into a first curved flow opening 559. The first curved flow opening 559 extends along a first azimuthal angle AA1 greater than 90 degrees around the outer face of an upper liner 563. A second curved flow opening 561 extends along a second azimuthal angle AA2 greater than 90 degrees around the outer face of a middle liner 515. The one or more gases P3 flow along the first and second curved flow openings 559, 561 and into the one or more flow housings 158 (FIG. 1). In one or more embodiments, the first azimuthal angle AA1 and the second azimuthal angle AA2 are respectively less than 330 degrees, such as less than 300 degrees. In one or more embodiments, the first azimuthal angle AA1 and the second azimuthal angle AA2 are respectively greater than 180 degrees.

In one or more embodiments the one or more gases P3 flow through the lower purge gas inlets 364 (FIG. 3) and into a third curved flow opening 562 and a fourth curved flow opening 564. The third curved flow opening 562 is a recess in the outer face of the middle liner 515 and the fourth curved flow opening 564 is a recess in the outer face of a lower liner 517. The one or more gases P3 flow along the third and fourth curved flow openings 562, 564 around the one or flow housings 158 and to the outer exhaust volume 188 through the gaps 187 (FIG. 1). The third curved flow opening 562 extends along a third azimuthal angle AA3 less than 180 degrees (such as less than 90 degrees) around the outer face of the middle liner 515. The fourth curved flow opening 564 extends along a fourth azimuthal angle AA4 less than 180 degrees (such as less than 90 degrees) around the outer face of the lower liner 517.

The present disclosure contemplates that the middle liner 515 and the lower liner 517 can respectively include an additional third curved flow opening 562 and an additional fourth curved flow opening 564 on opposing sides (e.g., on a back side of the view shown in FIG. 5) of the middle liner 515 and the lower liner 517.

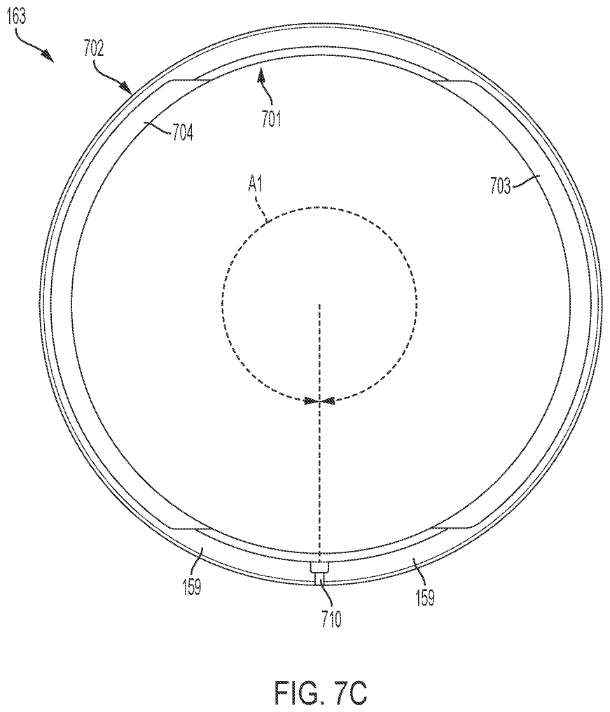

FIG. 6A is a schematic perspective profile view of material buildup on the chamber body using configurations described herein, according to one or more embodiments. The material buildup is on, for example, inner surfaces of the lower flow module 112 and the upper flow module 113. In one or more embodiments, the material buildup includes chlorine.

The profile view includes a first profile 601 having a first material concentration, a second profile 602 having a second material concentration higher than the first material concentration, and a third profile 603 having a third material concentration higher than the third material concentration.

FIG. 6B is a schematic perspective profile view of material buildup on the chamber body using other configurations.

As shown by comparing FIG. 6A with FIG. 6B, the subject matter described herein facilitates reduced buildup on the chamber body, as shown at least by the smaller third profile 603 in FIG. 6A compared to the third profile 603 in FIG. 6B. The reduced buildup can be facilitated, for example, at and/or near an inject area and an exhaust area of the chamber body.

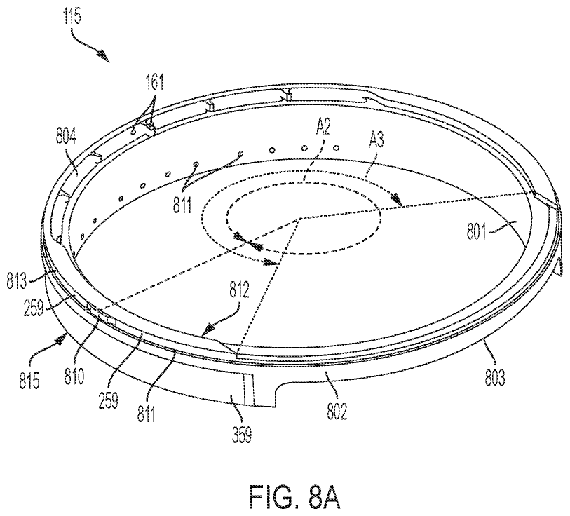

FIG. 7A is a schematic top isometric view of the upper liner 163 shown in FIGS. 1 and 4, according to one or more embodiments.

The upper liner 163 includes an inner face 701 and the outer face 702 opposing the inner face 701. The upper liner 163 includes an inlet opening 703 extending into the inner face 701 and an outlet opening 704 extending into the inner face 701. The first curved flow opening 159 extends into the outer face 702. The upper liner 163 includes a first side face 715 (e.g., a top face) and a second side face 712 (e.g., a bottom face) opposing the first side face 715. The first side face 715 and the second side face 712 extending between the inner face 701 and the outer face 702. In one or more embodiments, the first curved flow opening 159 is a recess extending into a second side face 712 of the upper liner 163 to define a shoulder 711 relative to the second side face 712. The upper liner 163 includes a flow protrusion 710 which is located on the outer face of the upper liner 163. The flow protrusion 710 includes a protrusion that extends into the first curved flow opening 159 which extends around the outer face 702 of the upper liner along the first azimuthal angle A1. In one or more embodiments a cross-flow gas can be injected through the flow protrusion 710 and flow across the processing volume 136 (FIG. 4) about perpendicular to the process gas P1 (FIG. 1). The flow protrusion 710 sized and shaped to extend into the first curved flow opening 159 such that the one or more gases P3 flowing in the first curved flow opening 159 can flow around (e.g., above and/or below) the flow protrusion 710. The one or more gases P3 flow from the upper liner purge inlets 210 (FIG. 2), through the first curved flow opening 159, and around the flow protrusion 710 and toward the 161 (FIG. 4).

FIG. 7B is a schematic bottom isometric view of the upper liner 163 shown in FIG. 7A, according to one or more embodiments.

FIG. 7C is a schematic bottom view of the upper liner 163 shown in FIG. 7A, according to one or more embodiments.

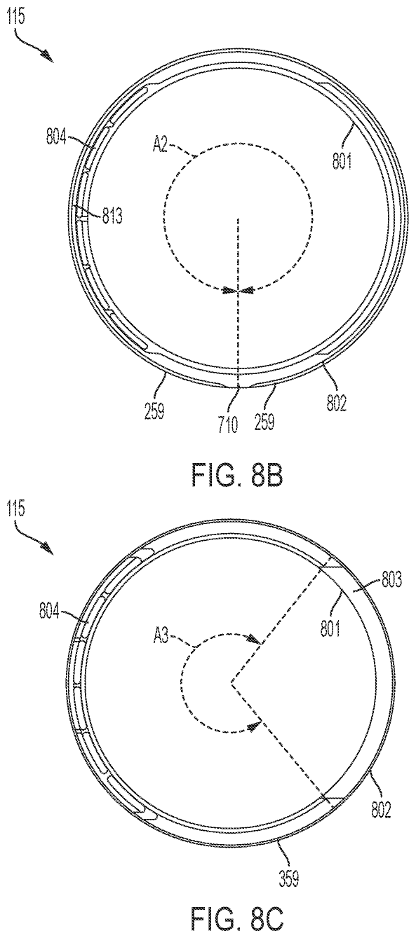

FIG. 8A is a schematic isometric view of the middle liner 115 shown in FIGS. 1 and 4, according to one or more embodiments.

The middle liner 115 includes an inner face 801, an outer face 802, an inlet opening 803, and one or more exhaust opening(s) 804 (a plurality is shown). The second curved flow opening 259 extends into the outer face 802. In one or more embodiments, the second curved flow opening 259 is a recess extending into a first side face 812 (e.g., a top face) of the middle liner 115 to define a shoulder 814 relative to the first side face 812. The middle liner 115 includes a second side face 815 (e.g., a bottom face) opposing the first side face 812. The first side face 812 and the second side face 815 extending between the inner face 801 and the outer face 802. The middle liner 115 includes a protrusion 810 which is located on the outer face 802 of the middle liner 115. The protrusion 810 extends into the second curved flow opening 259 which extends around the outer face 802 of the middle liner 115 along the second azimuthal angle A2. In one or more embodiments the cross-flow gas can be injected through the protrusion 810 and flow across the processing volume 136 (FIG. 4) about perpendicular to the process gas P1 (FIG. 1). The protrusion 810 is sized and shaped to extend into the second curved flow opening 259 such that the one or more gases P3 flowing in the second curved flow opening 259 can flow around (e.g., above and/or below) the protrusion 810. The one or more gases P3 flow from the upper liner purge inlets 210 (FIG. 2) within the second curved flow opening 159 and around the protrusion 810, through the through holes 161 and to the exhaust opening 804 at the opposite end of the middle liner 115. The middle liner 115 includes one more lower flow openings 811 through which the one or more purge gases P2 can flow though the exhaust opening(s) 804 to the one or more gas exhaust outlets 116 (FIG. 1). The middle liner 115 includes the third curved flow opening 359 which extends around the outer face 802 along the third azimuthal angle A3. In one or more embodiments, the one or more through holes 161 interface with the one or more exhaust openings 804 formed in the middle liner 115. The one or more exhaust openings 804 are at least part of the one or more gas exhaust outlets 116 shown in FIG. 1. The one or more through holes 161 extend into a recessed outer surface 813 at least partially defined by the second curved flow opening 259 of the middle liner 115.

FIG. 8B is a schematic top view of the middle liner 115 shown in FIG. 8A, according to one or more embodiments.

FIG. 8C is a schematic bottom view of the middle liner 115 shown in FIG. 8A, according to one or more embodiments.

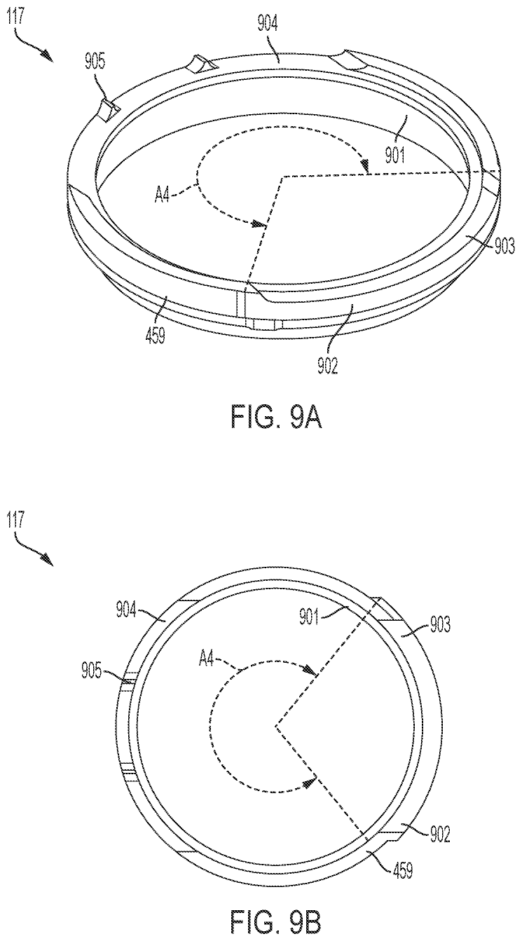

FIG. 9A is a schematic isometric view of the lower liner 117 shown in FIGS. 1 and 4, according to one or more embodiments.

The lower liner 117 includes an inner face 901, an outer face 902, an inlet opening 903, one or more exhaust openings 904 (a plurality is shown), one or more ridges 905 (a plurality is shown), and the fourth curved flow opening 459 which extends around the outer face 902 along the fourth azimuthal angle A4.

FIG. 9B is a schematic top view of the lower liner 117 shown in FIG. 9A, according to one or more embodiments.

The present disclosure contemplates that the upper liner 163 can be referred to as a first liner, the middle liner 115 can be referred to as a second liner, and/or the lower liner 117 can be referred to as a third liner.

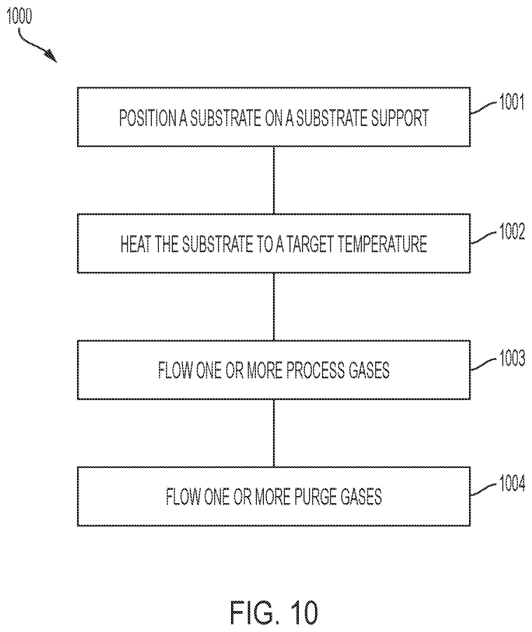

FIG. 10 is a schematic block diagram view of a method 1000 of substrate processing for semiconductor manufacturing, according to one or more embodiments.

Operation 1001 includes positioning a substrate on a substrate support in a processing volume of a processing chamber. In one or more embodiments, the positioning includes moving a substrate support and/or a plurality of lift pins relative to each other to land the substrate on the substrate support.

Operation 1002 of the method 1000 includes heating the substrate to a target temperature.

Operation 1003 includes flowing one or more process gases over the substrate.

Operation 1004 includes flowing one or more purge gases. In one or more embodiments, at least part of the purge gases flow around a chamber liner in a curved flow opening to a gas outlet. In one or more embodiments, a pressure is maintained inside the curved flow opening. In one or more embodiments operation 1004 is performed at least partially simultaneously with operation 1103.

Benefits of the present disclosure include reduced or eliminated chamber component corrosion, chamber component deposition, and/or chamber substrate contamination; reduced leakage of processing gases; and reduced or eliminated condensation of process gases on chamber components; reduced gas consumption and gas waste; and increased chamber component lifespans; increased growth rates; and more uniform film growth and/or dopant concentration. The chamber components can include, for example, flow modules (e.g., stainless steel or aluminum flow modules) and/or liners (e.g., transparent or opaque liners).

It is contemplated that one or more aspects disclosed herein may be combined. As an example, one or more aspects, features, components, operations and/or properties of the processing chamber 100; the upper liner 163; the middle liner 115; the lower liner 117; the upper flow module 113; the lower flow module 112; the upper liner purge inlet 210; the lower purge gas inlets 364, the gas inlet 114; the purge gas inlet 164; the gas exhaust outlet 116; the first curved flow opening 159; the second curved flow opening 259, the through hole(s) 161; the flow housings 158; the gaps 187; the outer exhaust volume 188; the third curved flow opening 359; the fourth curved flow opening 459; the upper liner 563; the middle liner 515; the lower liner 517; the flow protrusion 710; the protrusion 810; and/or the method 1000 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A substrate processing chamber, comprising:
one or more sidewalls at least partially defining a processing volume, the one or more sidewalls comprising a metallic body;
a substrate support disposed in the processing volume;
one or more heat sources operable to heat the processing volume;
a first liner disposed in the processing volume, the first liner disposed inwardly of the metallic body and abutting against the metallic body, the first liner comprising:
a first inner face;
a first outer face opposing the first inner face; and
a first flow opening extending into the first outer face and extending at least partially about the first liner, the first flow opening extending along a first azimuthal angle greater than 90 degrees, the first flow opening defining a flow channel between the first liner and the metallic body.

2. The processing chamber of claim 1, wherein the processing chamber further comprises:
a second liner at least partially supporting the first liner, the second liner comprising:
a second inner face;
a second outer face opposing the first inner face;
a second flow opening at least partially aligning with the first flow opening, the second flow opening extending into the second outer face and extending at least partially about the second liner, the second flow opening extending along a second azimuthal angle greater than 90 degrees; and
a third flow opening extending into the second outer face and extending at least partially about the second liner, the third flow opening extending along a third azimuthal angle greater than 90 degrees.

3. The processing chamber of claim 2, wherein the third azimuthal angle is greater than 180 degrees.

4. The processing chamber of claim 2, wherein the processing chamber further comprises a third liner at least partially supporting the second liner, the third liner comprising:
a third inner face;
a third outer face opposing the first inner face; and
a fourth flow opening at least partially aligning with the third flow opening, the fourth flow opening extending into the third outer face and extending at least partially about the third liner, the fourth flow opening extending along a fourth azimuthal angle greater than 90 degrees.

5. The processing chamber of claim 2, wherein the first flow opening is a recess extending into the first outer face, and the processing chamber further comprises:
a ring disposed between the first liner and the second liner.

6. The processing chamber of claim 2, wherein the processing chamber further comprises:
a gas inlet; and
a gas exhaust.

7. The processing chamber of claim 6, wherein the second liner further comprises:
one or more through holes extending between the second inner face and the second outer face.

8. The processing chamber of claim 7, wherein the one or more through holes interface with one or more exhaust openings formed in the second liner.

9. A liner for a substrate processing chamber, comprising:
an inner face;
an outer face opposing the inner face;
an inlet opening extending into the inner face;
an outlet opening extending into the inner face; and
a curved flow opening extending into the outer face and extending at least partially about the liner, the curved flow opening extending along an azimuthal angle greater than 90 degrees.

10. The liner of claim 9, wherein the liner comprises an opaque material.

11. The liner of claim 9, wherein the azimuthal angle is greater than 180 degrees.

12. The liner of claim 9, wherein the curved flow opening is a recess that at least partially defines a shoulder along the outer face.

13. The liner of claim 9, wherein the liner further comprises:
a first side face extending between the inner face and the outer face; and
a second side face extending between the inner face and the outer face, the second side face opposing the first side face,
wherein the curved flow opening, the inlet opening, and the outlet opening extend into the second side face.

14. A chamber kit for a substrate processing chamber, comprising:
a first liner comprising:
a first inner face;
a first outer face opposing the first inner face; and
a first flow opening extending into the first outer face and extending at least partially about the first liner, the first flow opening extending along a first azimuthal angle greater than 90 degrees; and
a second liner comprising:
a second inner face;
a second outer face opposing the first inner face; and
a second flow opening sized and shaped to at least partially align with the first flow opening, the second flow opening extending into the second outer face and extending at least partially about the second liner, the second flow opening extending along a second azimuthal angle greater than 90 degrees.

15. The chamber kit of claim 14, wherein the second flow opening is a recess.

16. The chamber kit of claim 14, wherein the second liner further comprises:
a third flow opening extending into the second outer face and extending at least partially about the second liner, the third flow opening extending along a third azimuthal angle greater than 90 degrees.

17. The chamber kit of claim 16, wherein the second liner further comprises:
a first side face extending between the second inner face and the second outer face; and
a second side face extending between the second inner face and the second outer face, the second side face opposing the first side face,
wherein the second flow opening extends into the first side face and the third flow opening extends into the second side face.

18. The chamber kit of claim 14, wherein the second liner further comprises:
one or more through holes extending between the second inner face and the second outer face.

19. The chamber kit of claim 18, wherein the one or more through holes extend into a recessed outer surface at least partially defined by the second flow opening of the second liner.

20. The chamber kit of claim 14, wherein the first azimuthal angle and the second azimuthal angle are respectively greater than 180 degrees.
